(19) United States
(12) Patent Application Publication
(10) Pub. No.: US 2013/0180750 A1
(43) Pub. Date: Jul. 18, 2013

(54) COVER ATTACHMENT STRUCTURE AND ELECTRONIC DEVICE

(71) Applicant: Panasonic Corporation, Osaka (JP)

(72) Inventor: YOUICHI FUJIWARA, Osaka (JP)

(73) Assignee: PANASONIC CORPORATION, Osaka (JP)

(21) Appl. No.: 13/719,342

(22) Filed: Dec. 19, 2012

(30) Foreign Application Priority Data
Jan. 16, 2012 (JP) 2012-005795

(51) Int. Cl. H05K 7/00

(52) U.S. Cl. CPC H05K 7/00
USPC 174/50

(57) ABSTRACT

A cover attachment structure used in an electronic device comprises a frame that allows one of a first terminal cover for covering at least a terminal and a second terminal cover for covering the terminal and a second terminal to be mounted selectively so as to enable the terminal cover to be opened and closed, a protrusion that is provided to the frame so as not to interfere with the second terminal cover in a state in which the second terminal cover has been mounted to the frame, and that can engage with the first terminal cover, and a protrusion that is provided on the frame so as not to interfere with the first terminal cover in a state in which the first terminal cover has been mounted to the frame, and that can engage with the second terminal cover.

### BACKGROUND OF THE INVENTION

1. Technical Field

The technical field relates to a cover attachment structure, and to an electronic device equipped with this structure.

2. Description of the Related Art

Digital cameras and other such electronic devices are provided with terminals for connecting to external devices. These electronic devices have a constitution in which the terminals are covered with a cover in order to protect the terminals when they are not being used, and to improve the appearance of the product. Patent Literature 1 discloses a constitution in which a cover member is combined with a hinge member formed from a material that is softer and more flexible than the cover member.

### CITATION LIST

### Patent Literature

Patent Literature 1: Japanese Laid-Open Patent Application 2004-234861

### SUMMARY

There are situations in which a plurality of models of an electronic device are manufactured and sold that have substantially the same housing shape, but have different numbers of terminals due to differences in the functions provided to the models. For instance, higher-end models come with video output terminals, while lower-end models do not. With a plurality of models such as this, it is desirable from an aesthetic standpoint to provide covers of the appropriate size according to the different numbers of terminals provided.

However, if the sizes of the covers are different, then even though the main housing panels and so forth can be shared, it is necessary to prepare a plurality of frames for attaching the covers, or housing panels that are adjacent to the covers, according to the sizes of the covers, making it difficult to share these portions across models. Therefore, it was difficult to reduce the number of parts needed for the entire model line.

This disclosure was conceived in light of the above situation, and provides a cover attachment structure and an electronic device with which parts can be shared among a plurality of models equipped with covers of different sizes.

The cover attachment structure used in an electronic device in this disclosure comprises a frame to which a first cover for covering at least a first region and a second cover for covering a second region that includes the first region are mounted so as to allow one of the covers to be selectively opened and closed, a first attachment component that is provided on the frame so as not to interfere with the second cover in a state in which the second cover has been mounted to the frame, and that can be engaged with the first cover, and a second attachment component that is provided on the frame so as not to interfere with the first cover in a state in which the first cover has been mounted to the frame, and that can be engaged with the second cover.

The cover attachment structure and electronic device in this disclosure can share parts across a plurality of models equipped with covers of different sizes.

### BRIEF DESCRIPTION OF DRAWINGS

FIG. 1A is an oblique view from the front face side of a digital camera 100B pertaining to Embodiment 1, and FIG. 1B is an oblique view from the rear face side of the digital camera 100B pertaining to Embodiment 1;

FIG. 2A is a side view of a digital camera 100A pertaining to Embodiment 1, and FIG. 2B is a front view of the digital camera 100A pertaining to Embodiment 1;

FIG. 3A is a side view of the digital camera 100A pertaining to Embodiment 1, and FIG. 3B is a front view of the digital camera 100A pertaining to Embodiment 1;

FIG. 4 is an exploded oblique view of the digital camera 100A pertaining to Embodiment 1;

FIG. 5 is an exploded oblique view of the digital camera 100B pertaining to Embodiment 1;

FIG. 6 is a detail enlargement of the area around a first terminal cover 50A of the digital camera 100A pertaining to Embodiment 1;

FIG. 7 is a detail enlargement of the area around a second terminal cover 50B of the digital camera 100B pertaining to Embodiment 1;

FIG. 8 is a detail enlargement of the area around the first terminal cover 50A of the digital camera 100A pertaining to Embodiment 1;

FIG. 9 is a detail enlargement of the area around the second terminal cover 50B of the digital camera 100B pertaining to Embodiment 1;

FIG. 10 is an oblique view of a modification example of the cover attachment structure pertaining to Embodiment 1;

FIG. 11 is an oblique view of a modification example of the cover attachment structure pertaining to Embodiment 1;

FIG. 12 is an oblique view of a modification example of the cover attachment structure pertaining to Embodiment 1;

FIG. 13 is an oblique view of a modification example of the cover attachment structure pertaining to Embodiment 1;

FIG. 14 is an oblique view of a modification example of the cover attachment structure pertaining to Embodiment 1;

FIG. 15 is an oblique view of a modification example of the cover attachment structure pertaining to Embodiment 1; and

FIG. 16 is an oblique view of a modification example of the cover attachment structure pertaining to Embodiment 1.

### DETAILED DESCRIPTION OF THE PREFERRED EMBODIMENTS

Next, an embodiment will be described in detail through reference to the drawings as needed. Unnecessarily detailed description will be omitted, however. For example, detailed description of things that are already known, or redundant description of components that are substantially the same may be omitted. This is to avoid making the following description unnecessarily repetitive, and to facilitate an understanding on the part of a person skilled in the art. Also, in the description of the drawings below, portions that are the same or similar will be given the same or similar numbers. The drawings are merely schematics, however, and the actual dimensional proportions and so forth may differ from what is depicted. Therefore, specific dimensions and the like should be determined by referring to the following description. Naturally, dimensional relations and proportions may vary from one drawing to the next.

Specifically, the appended drawings and the following description are provided so that a person skilled in the art will full understand this disclosure, and are not intended to limit the main ideas set forth in the Claims.

In the following embodiments, a digital camera will be described as an example of an electronic device equipped with a cover. In the following description, using a digital camera in its normal orientation (hereinafter also referred to as landscape orientation) as a reference, the direction facing the subject is expressed as “forward,” the direction facing away from the subject as “rearward,” vertically upward as “upward,” vertically downward as “downward,” to the right in a state of directly facing the subject as “to the right,” and to the left in a state of directly facing the subject as “to the left.”

### Embodiment 1

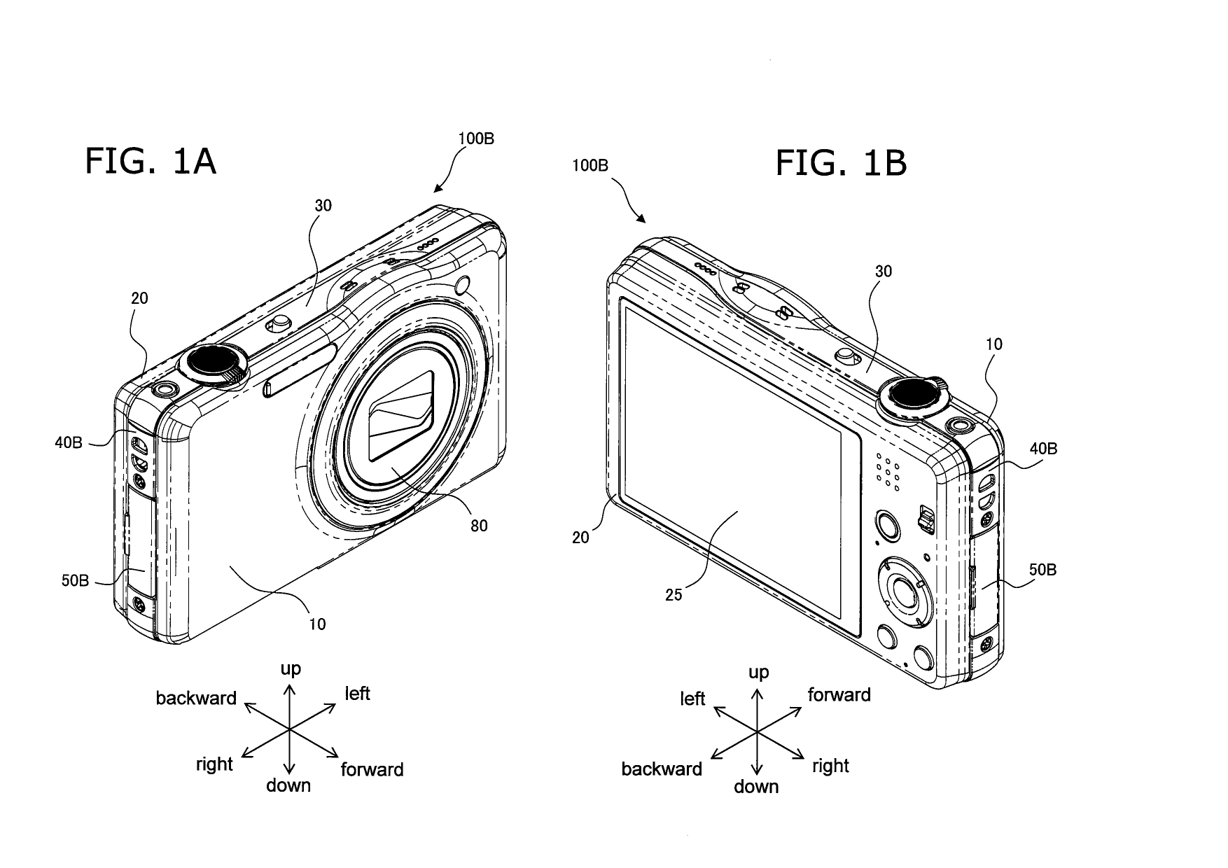

Embodiment 1 will now be described through reference to FIGS. 1 to 9.

### 1-1. Overall Configuration of Digital Cameras 100A and 100B

The digital cameras 100A and 100B of this embodiment differ from each other in the number of terminals for connecting to an external device. Therefore, the terminal covers used to cover the terminals (an example of a cover) each have a different size. The cameras share the rest of their components. Although discussed in detail below, in particular a frame 60 is shared by both types of digital camera because it is configured so as to allow the attachment of both a first terminal cover 50A, which is a cover corresponding to the digital camera 100A, and a second terminal cover 50B, which is a cover corresponding to the digital camera 100B. This allows a reduction in the total number of parts required by the two types of digital camera.

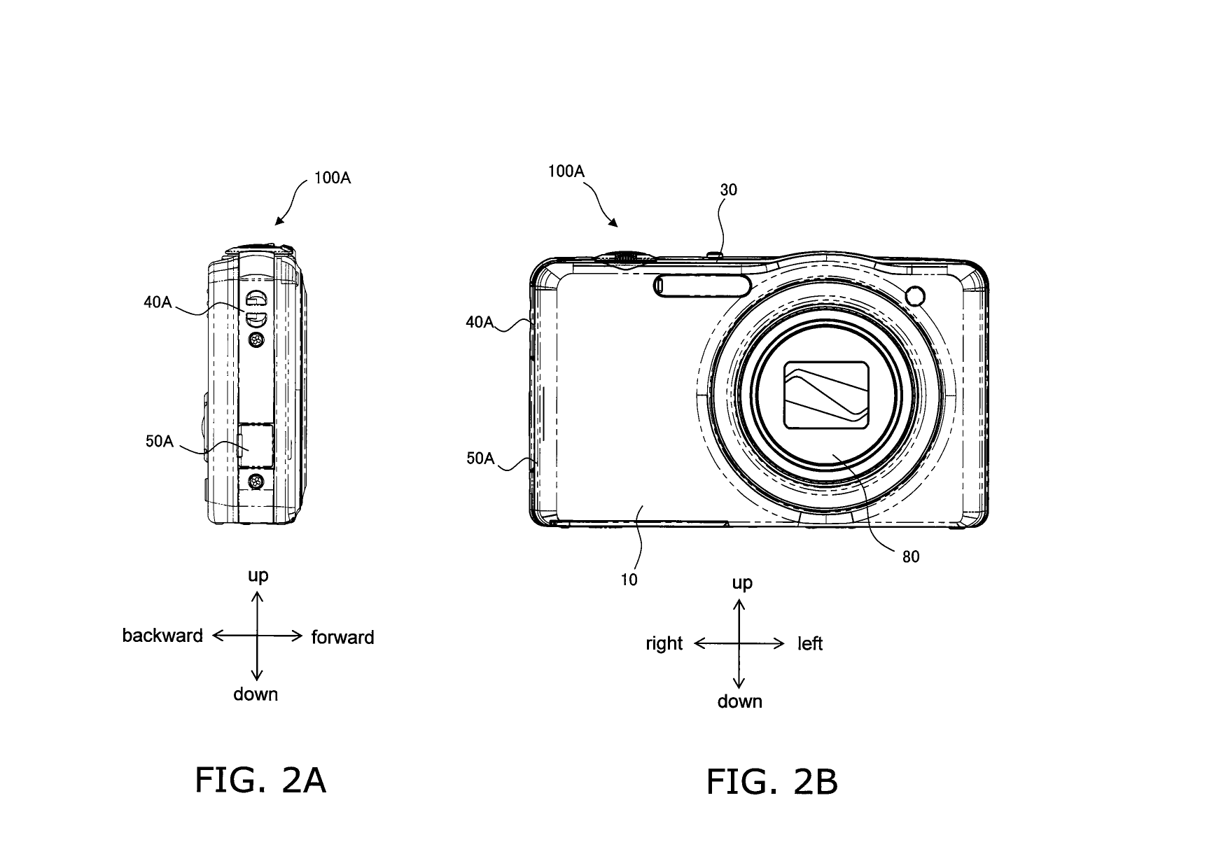

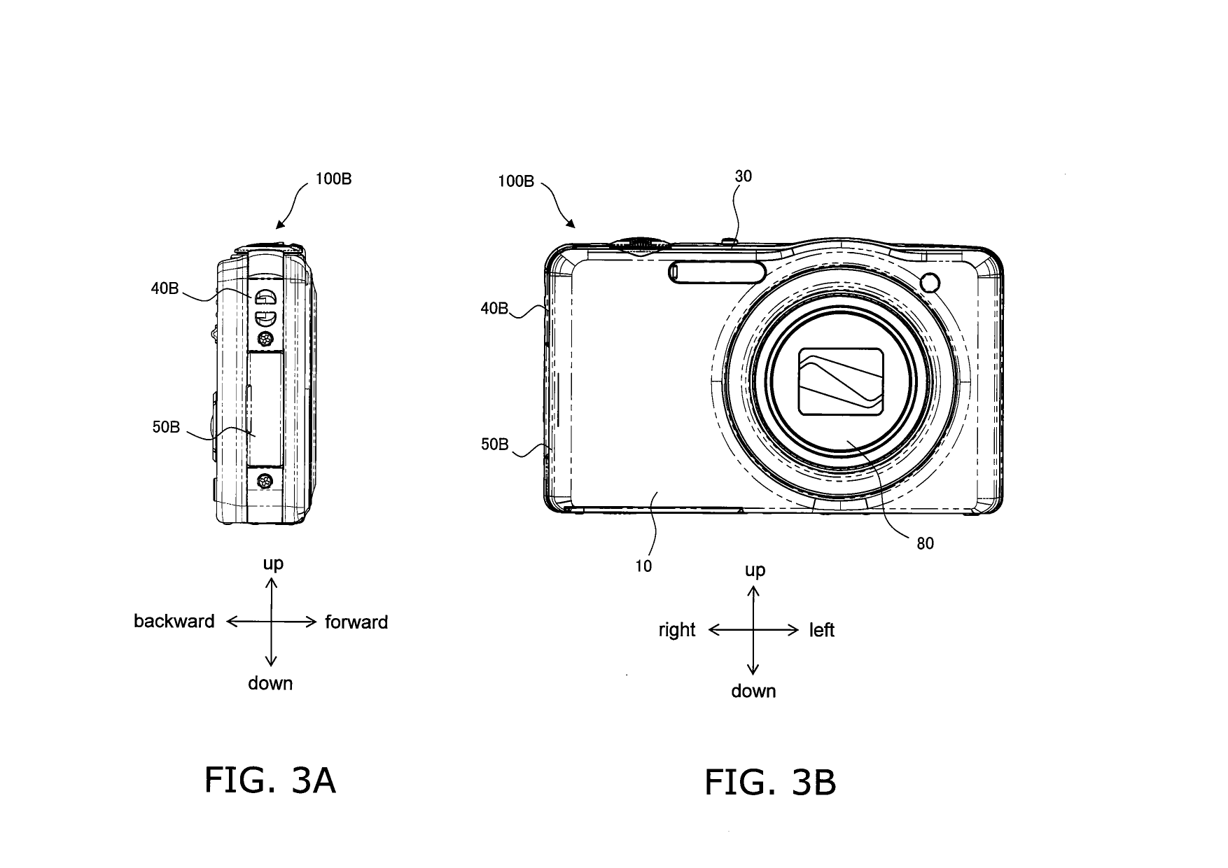

FIG. 1A is an oblique view from the front of the digital camera 100B pertaining to Embodiment 1. FIG. 1B is an oblique view from the rear of the digital camera 100B pertaining to Embodiment 1. FIG. 2A is a side view from the right side of the digital camera 100A pertaining to Embodiment 1. FIG. 2B is a front view of the digital camera 100A pertaining to Embodiment 1. FIG. 3A is a side view of the digital camera 100B pertaining to Embodiment 1 as seen from the right. FIG. 3B is a front view of the digital camera 100B pertaining to Embodiment 1.

The digital cameras in Embodiment 1 appear to have the same configuration, except for the area around the terminal covers. Therefore, first we will refer to FIG. 1 to describe the appearance using the digital camera 100B as an example.

The digital camera 100B comprises a front panel 10 (an example of a plate-shaped member), a rear panel 20, an upper panel 30, a side panel 40B, the second terminal cover 50B, a monitor 25, and a lens 80. The front panel 10, the rear panel 20, the upper panel 30, and the side panel 40B constitute the “housing” pertaining to this embodiment.

The front panel 10 constitutes the panel on the front side of the housing. The front panel 10 is disposed so that the plane with the largest surface area faces forward. The rear panel 20 constitutes a panel on the rear side of the housing. The upper panel 30 constitutes a panel on the upper side of the housing. The side panel 40B constitutes a panel on the right side of the housing. The left side face of the housing is constituted by bending in the left end of the front panel 10 and the left end of the rear panel 20. The second terminal cover 50B is used to cover terminals disposed on the side panel 40B. The second terminal cover 50B is attached openably and closeably to the side panel 40B. The monitor 25 is fixed to the inner face of the rear panel 20. The lens 80 is disposed on the inner face side of the front panel 10. The lens 80 is deployed when the power is switched on to the digital camera 100B, resulting in a state that allows imaging.

The digital camera 100A shown in FIG. 2 has basically the same configuration as the digital camera 100B. In terms of appearance, the only difference is in the configuration of the side panels and terminal covers, with the side panel 40B and the second terminal cover 50B being provided to the digital camera 100B, and a side panel 40A and the first terminal cover 50A provided to the digital camera 100A.

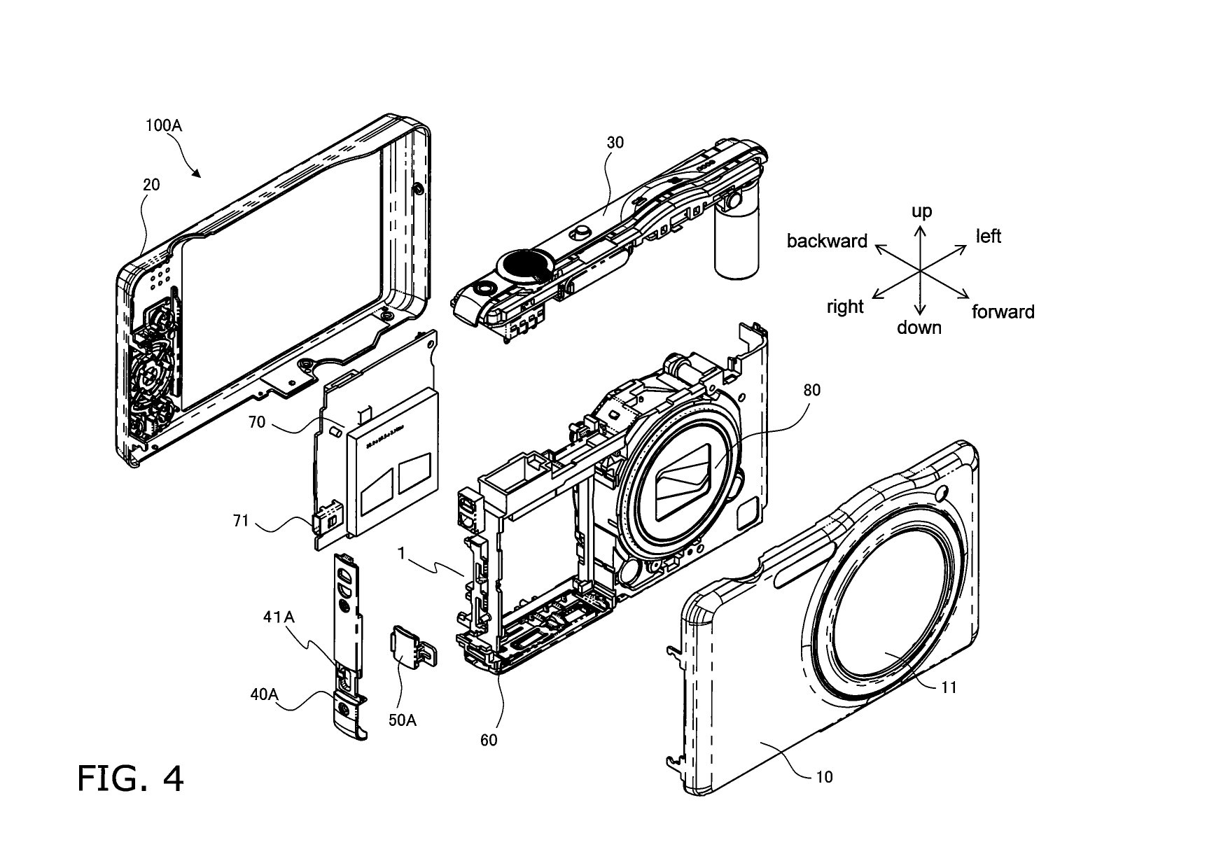

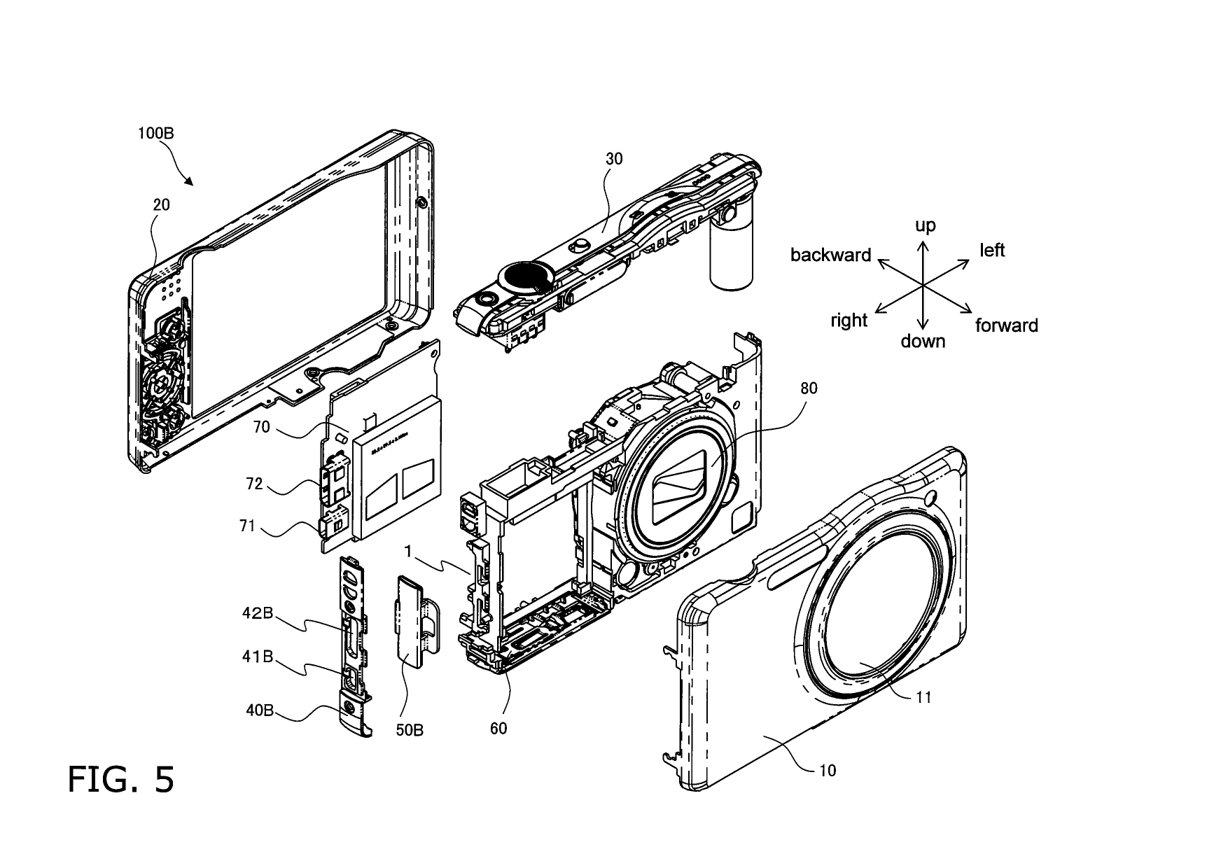

The digital camera 100A comprises one terminal for connecting to an external device (the terminal 71 shown in FIG. 4 and discussed below). The digital camera 100B, meanwhile, comprises two terminals for connecting to an external device. These two terminals (the terminals 71 and 72 shown in FIG. 5 and discussed below) are disposed one over the other in the up and down direction. Therefore, the terminal covers correspond to this, and the first terminal cover 50A of the digital camera 100A has a width in the up and down direction that is enough to cover one terminal. The second terminal cover 50B of the digital camera 100B has a width in the up and down direction that is enough to cover two terminals. Therefore, the width of the second terminal cover 50B in the up and down direction and greater than the width of the first terminal cover 50A in the up and down direction.

FIG. 4 is an exploded oblique view of the digital camera 100A. The frame 60 comprises the lens 80. When the front panel 10 is attached at the front of the frame 60, the lens 80 can be deployed through an opening 11. A substrate 70 is attached on the right rear side of the frame 60. With the digital camera 100A, the terminal 71 is provided to the substrate 70, and connection to an external device is possible from the right side.

The upper panel 30 is attached to the top of the frame 60, and the rear panel 20 is attached to the rear.

The first terminal cover 50A is attached from the right side face of the frame 60, and the side panel 40A is attached from the right side face to fix the first terminal cover 50A. The portion of the side panel 40A that is opposite the terminal 71 is provided with a hole 41A. Therefore, when the side panel 40A is attached to the frame 60, the terminal 71 is exposed through the hole 41A. A cover attachment structure 1 is provided for attaching this first terminal cover 50A to the frame 60.

FIG. 5 is an exploded oblique view of the digital camera 100B. The frame 60 comprises the lens 80. When the front panel 10 is attached at the front of the frame 60, the lens 80 can be deployed through the opening 11. The substrate 70 is attached on the right rear side of the frame 60. With the digital camera 100B, the terminal 71 and the terminal 72 are provided to the substrate 70, and connection to an external device is possible from the right side. The upper panel 30 is attached to the top of the frame 60, and the rear panel 20 is attached to the rear. The second terminal cover 50B is attached from the right side face of the frame 60, and the side panel 40B is attached from the right side face to fix the second terminal cover 50B. The portions of the side panel 40B that are opposite the terminal 71 and the terminal 72 are respectively provided with a hole 41B and a hole 42B, so when the side panel 40B is attached to the frame 60, the terminal 71 is exposed through the hole 41B, and the terminal 72 through the hole 42B. A cover attachment structure 1 is provided for attaching the second terminal cover 50B for covering these terminals 71 and 72 to the frame 60.

### 1-2. Detailed Configuration of Area Around First Terminal Cover 50A of Digital Camera 100A

The configuration of the area around the first terminal cover 50A will now be described along with the configuration of the cover attachment structure 1.

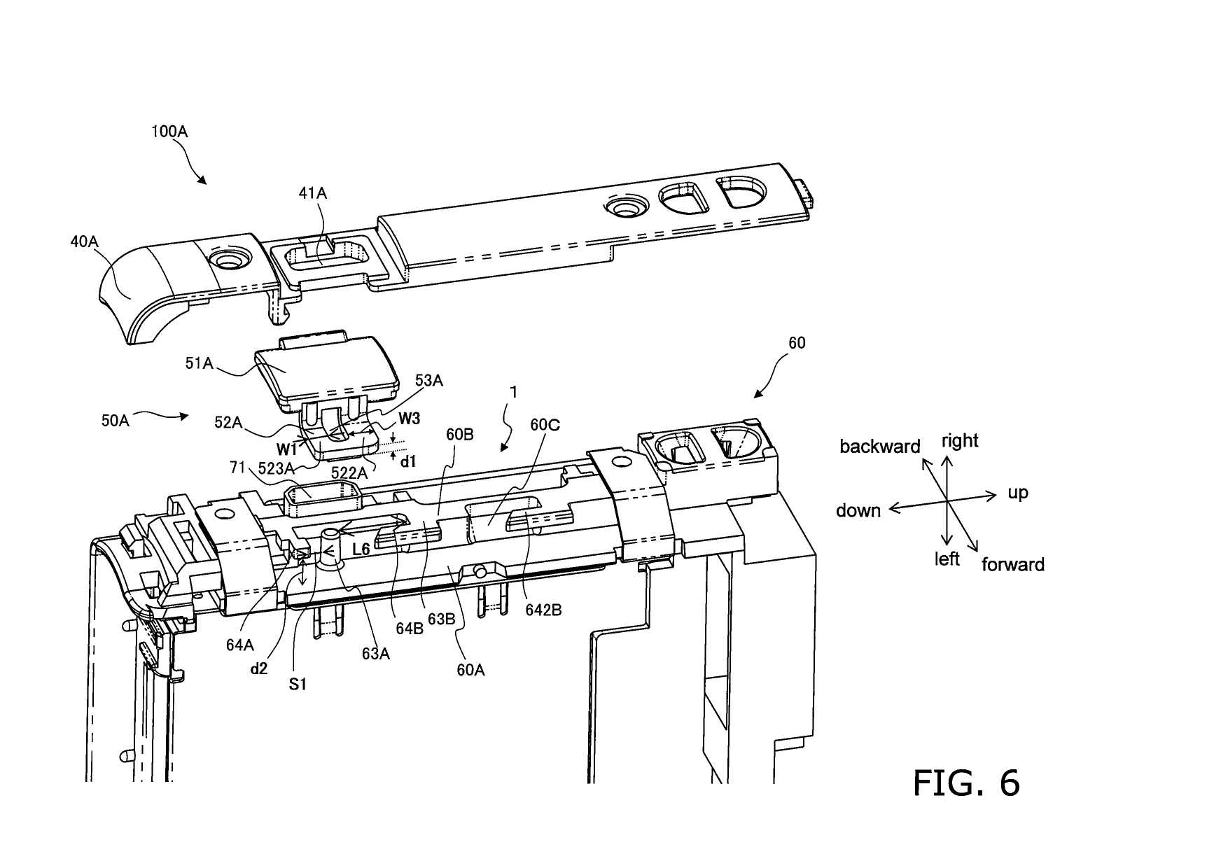

FIG. 6 is a detail enlargement of the area around a first terminal cover 50A of the digital camera 100A. The cover attachment structure 1 of Embodiment 1 comprises the frame 60, a protrusion 63A (an example of a first protrusion and a first attachment component) formed on the right side face of the frame 60, a restrictor 64A (an example of a first restrictor), a protrusion 63B (an example of a second protrusion and a second attachment component), a restrictor 64B (an example of a second restrictor), and a restrictor 642B (an example of a second restrictor).

The frame 60 has a substantially stepped shaped in which the front side is formed more to the left side than the rear, and has a front step part 60A of the front side of the stepped shape, a rear step part 60B on the rear side of the stepped shape, and a riser part 60C that links the front step part 60A and the rear step part 60B.

The protrusion 63A is provided to pass through a first hole 53A in the first terminal cover 50A and to attach a first cover part 51A to the frame 60. This protrusion 63A is provided so as to stick out to the right from the front step part 60A at a position in front of the terminal 71 when the substrate 70 is attached to the frame 60.

The restrictor 64A is provided under the protrusion 63A to restrict the first terminal cover 50A from moving away from over the frame 60, and to temporarily hold it in place. This restrictor 64A is formed from the rear step part 60B so as to stick out toward the protrusion 63A at a specific distance away from the protrusion 63A. That is, the restrictor 64A has a distal end shape that projects to the protrusion 63A side, and the spacing S1 between the protrusion 63A and the restrictor 64A is narrower than the width W1 of a portion 523A of a first hinge component 52A that is on the lower side of the first hole 53A. Also, a specific gap d2 is provided between the restrictor 64A and the front step part 60A, and this specific gap d2 is configured to be slightly larger than the thickness d1 of the first hinge component 52A.

The first terminal cover 50A has the first cover part 51A, the first hinge component 52A, and the first hole 53A, and is used for the purpose of covering the terminal 71. The first hinge component 52A, which is made from an elastic material, is disposed protruding in front of the first cover part 51A. The first hole 53A is provided in the middle part of the first hinge component 52A. The first hole 53A is larger than the protrusion 63A so that the protrusion 63A can be passed through. The region of the frame 60 that is around the terminal 71 is an example of a first region.

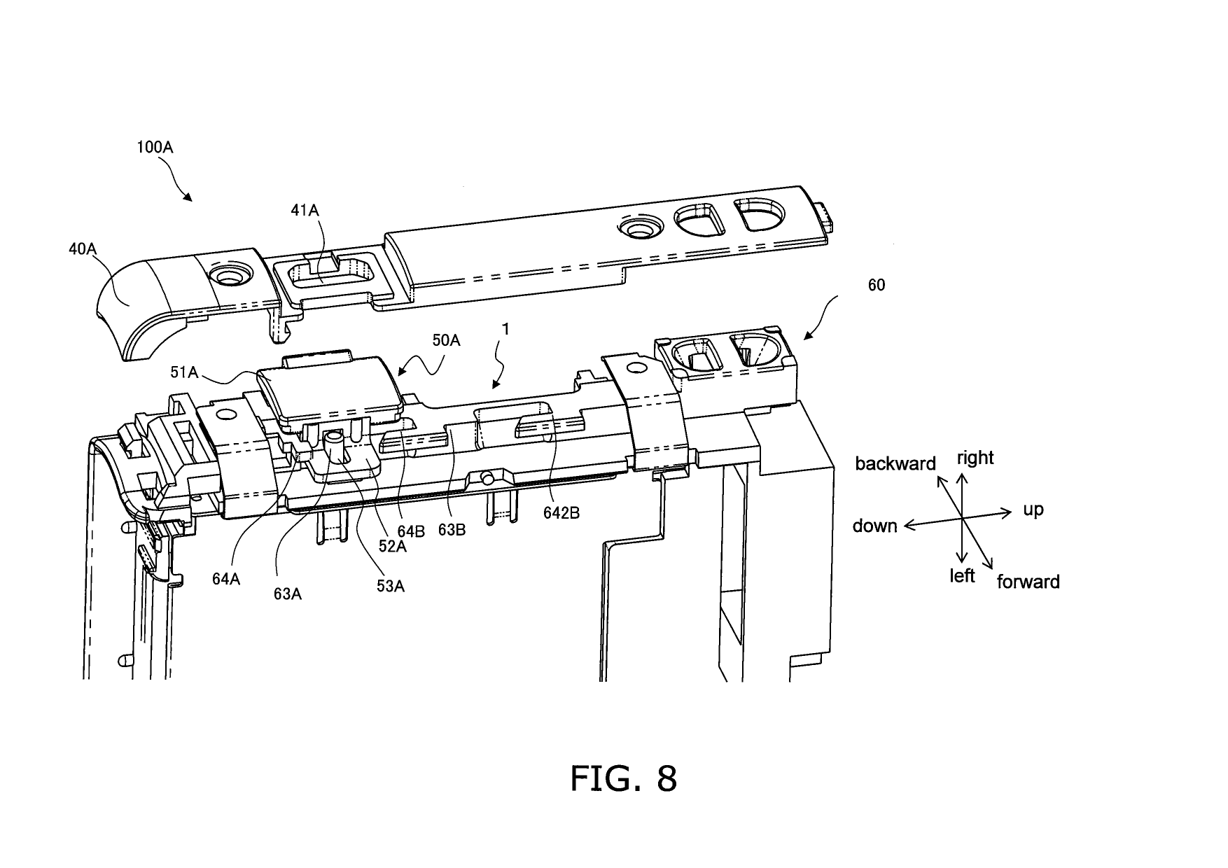

FIG. 8 is a diagram of how the first terminal cover 50A is attached to the frame 60. Because of the dimensional relations discussed above, when the protrusion 63A is inserted into the first hole 53A to attach the first terminal cover 50A to the frame 60, the restrictor 64A prevents the first terminal cover 50A from falling off and restricts it to rotation around the protrusion 63A. Consequently, the first terminal cover 50A is temporarily held in place on the frame 60.

The hole 41A is provided to the side panel 40A, and when the side panel 40A is attached to the frame 60, the terminal 71 fits into the hole 41A and is exposed through the hole 41A. As a result of the side panel 40A being attached to the frame 60, the first hinge component 52A is pressed by the side panel 40A, and the first terminal cover 50A is completely fixed to the frame 60. 1-3. Detailed Configuration of Area Around Second Terminal Cover 50B of Digital Camera 100B

The configuration of the area around the second terminal cover 50B will now be described along with the configuration of the cover attachment structure 1.

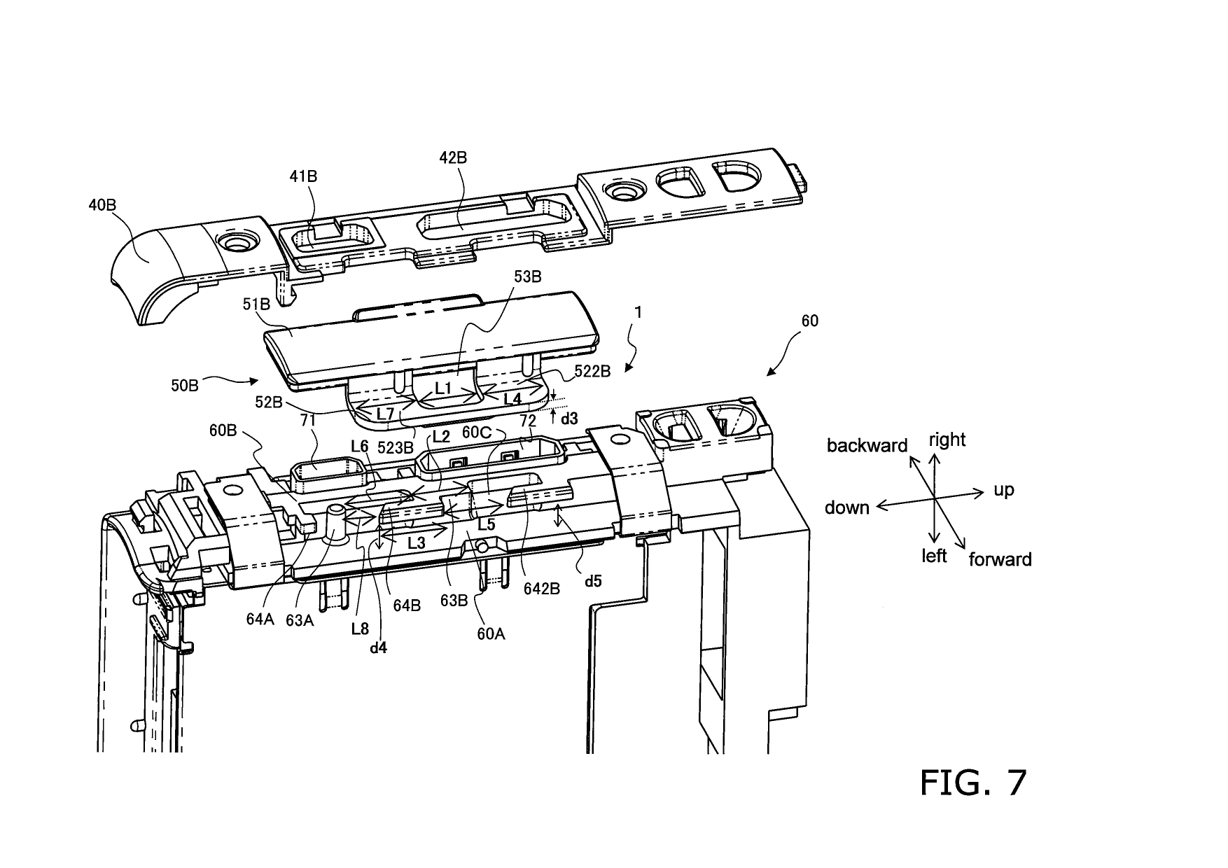

FIG. 7 is a detail enlargement of the area around the second terminal cover 50B of the digital camera 100B. The cover attachment structure 1 and the frame 60 of the digital camera 100B are the same as those of the digital camera 100A, and therefore those components already discussed will not be described again.

The protrusion 63B is provided to pass through a second hole 53B of the second terminal cover 50B and to attach a second cover 51B to the frame 60. This protrusion 63B is disposed in front of the approximate middle between the terminal 71 and the terminal 72, which are disposed one above the other in the up and down direction, and is provided so as to stick out to the right from this position of the front step part 60A, when the substrate 70 is attached to the frame 60. The protrusion 63B can also be said to be formed so as to stick out forward from the riser part 60C.

The restrictor 64B and the restrictor 642B are provided to restrict the second terminal cover 50B from moving away from over the frame 60, and to temporarily hold it in place. The restrictor 64B is provided so as to stick out downward from the distal end of the protrusion 63B. The restrictor 642B is provided so as to stick out downward from the rear step part 60B at a position above the restrictor 64B. Specific gaps d4 and d5 are provided between the restrictor 64B and the front step part 60A, and between the restrictor 642B and the front step part 60A, respectively, and these specific gaps d4 and d5 are configured so as to be slightly larger than the thickness d3 of a second hinge component 52B.

The second terminal cover 50B has the second cover 51B, the second hinge component 52B, and the second hole 53B, and is used for the purpose of covering the terminals 71 and 72. The second hinge component 52B, which is made from an elastic material, is disposed protruding in front of the second cover 51B. The second hole 53B is provided in the middle part of the second hinge component 52B. The second hole 53B is larger than the protrusion 63B so that the protrusion 63B can be passed through. The regions of the frame 60 that are around the terminals 71 and 72 are an example of a second region that includes the first region.

The restrictor 64B and the restrictor 642B have a shape that sticks out downward to prevent the second hinge component 52B from falling off. More precisely, they have the following dimensional relations. If we let L1 be the width of the second hole 53B in the up and down direction, L2 be the width of the protrusion 63B in the up and down direction, L3 be the width of the restrictor 64B in the up and down direction, L4 be the width of the portion 522B of the second hinge component 52B that is above the second hole 53B, and L5 be the spacing between the restrictor 64B and the restrictor 642B, then L2 and L3 are substantially equal, and L1 is slightly greater than L2 and L3. Also, L5 is slightly greater than L4. Since L1 is slightly greater than L2 and L3, the restrictor 64B can pass through the inside of the second hole 53B, and the protrusion 63B can be disposed inside the second hole 53B. Also, since L5 is slightly greater than L4, the portion 522B on the upper side of the second hinge component 52B can pass between the restrictor 64B and the restrictor 642B.

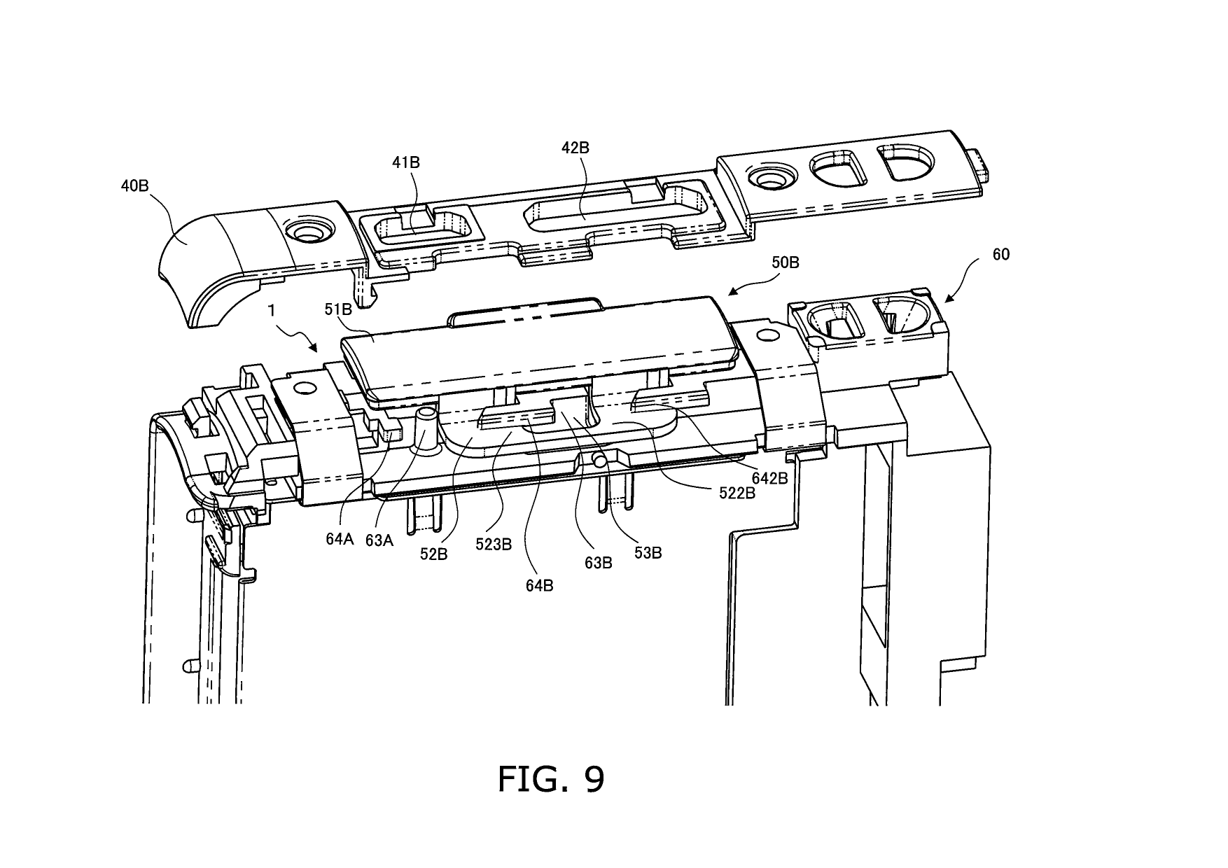

FIG. 9 is a diagram of how the second terminal cover 50B is attached to the frame 60. Because of the above-mentioned dimensional relations, when the second hinge component 52B is attached to the frame 60, the protrusion 63B is inserted through the restrictor 64B into the second hole 53B of the second terminal cover 50B, and the second terminal cover 50B is moved upward until it touches the restrictor 64B, and as a result, the second hinge component 52B is supported by the restrictor 64B and the restrictor 642B and temporarily fixed to the frame 60. The holes 41B and 42B are provided to the side panel 40B, and when the side panel 40B is attached to the frame 60, the terminals 71 and 72 are fitted into the holes 41B and 42B, respectively, the terminal 71 is exposed through the hole 41B, and the terminal 72 through the hole 42B. When the side panel 40B is attached to the frame 60, the second hinge component 52B is pressed by the side panel 40B, and the second terminal cover 50B is completely fixed.

### 1-4. Layout Relation Between Second Terminal Cover and Protrusion and Restrictor Used for First Terminal Cover

The protrusion 63A and the restrictor 64A are provided so as not to interfere with the second terminal cover 50B in a state in which the second terminal cover 50B has been attached to the frame 60. The term “interfere” here means that providing the protrusion 63A and the restrictor 64A prevents the second terminal cover 50B from being attached to the frame 60, and since there is no interference in this embodiment, the second terminal cover 50B can be attached to the frame 60 even though the protrusion 63A and the restrictor 64B are provided for the first terminal cover 50A.

In Embodiment 1, the distance L6 from the protrusion 63B to the protrusion 63A (see FIG. 7) is set to be greater than the width L7 of the portion 523B of the second hinge component 52B below the second hole 53B (see FIG. 7) so that the protrusion 63A will not interfere with the second terminal cover 50B. Specifically, the protrusion 63A is provided at a position on the frame 60 where it will not interfere with the second hinge component 52B of the second terminal cover 50B in a state in which the second terminal cover 50B has been attached to the frame 60. Also, the restrictor 64A is disposed on the opposite side from the protrusion 63B, with the protrusion 63A in between, so that the restrictor 64A will not interfere with the second terminal cover 50B.

### 1-5. Layout Relation Between First Terminal Cover and Protrusion and Restrictor Used for Second Terminal Cover

The protrusion 63B, the restrictor 64B, and the restrictor 642B are provided so as not to interfere with the first terminal cover 50A in a state in which the first terminal cover 50A has been attached to the frame 60. The term “interfere” here means that providing the protrusion 63B, the restrictor 64B, and the restrictor 642B prevents the first terminal cover 50A from being attached to the frame 60, and since there is no interference in this embodiment, the first terminal cover 50A can be attached to the frame 60 even though the protrusion 63B, the restrictor 64B, and the restrictor 642B are provided for the second terminal cover 50B.

In Embodiment 1, the distance L6 from the protrusion 63B to the protrusion 63A is set to be greater than the width W3 of the portion 522A of the first hinge component 52A that is above the first hole 53A (see FIG. 6), so that the protrusion 63B will not interfere with the first terminal cover 50A. Specifically, the protrusion 63B is provided at a position on the frame 60 where it will not interfere with the first hinge component 52A of the first terminal cover 50A in a state in which the first terminal cover 50A has been attached to the frame 60. Also, even though the spacing L8 between the protrusion 63A and the lower distal end of the restrictor 64B (see FIG. 7) is less than the width W3, since the spacing between the restrictor 64B and the front step part 60A is slightly greater than the thickness of the second hinge component 52B, the restrictor 64B does not interfere with the first terminal cover 50A in an attached state. Furthermore, even though the spacing L8 between the protrusion 63A and the lower distal end of the restrictor 64B (see FIG. 7) is less than the width W3, since the first hinge component 52A is formed from an elastic member, the first hinge component 52A can be bent so that the first hinge component 52A goes under the restrictor 64B, which allows the first terminal cover 50A to be attached to the frame 60.

### 1-6. Action, Effect, etc.

As discussed above, in this embodiment, the cover attachment structure 1 comprises the frame 60, the protrusion 63A (an example of a first attachment component), and the protrusion 63B (an example of a second attachment component). One of the first terminal cover 50A (an example of a first cover) for covering a region including at least the terminal 71 (an example of a first region) and the second terminal cover 50B (an example of a second cover) for covering a region that includes the terminal 71 and the terminal 72 (an example of a second region) is allowed to be mounted selectively to the frame 60. The selected cover (one of the first terminal cover 50A and the second terminal cover 50B) is mounted to the frame 60 so as to be allowed to be opened and closed. The protrusion 63A (an example of a first attachment component) is provided at a position on the frame 60 where it will not interfere with the second terminal cover 50B in a state in which the second terminal cover 50B has been mounted to the frame 60. The protrusion 63A can engage with the first hole 53A formed in the first hinge component 52A of the first terminal cover 50A. The protrusion 63B (an example of a second attachment component) is provided at a position on the frame 60 where it will not interfere with the first terminal cover 50A in a state in which the first terminal cover 50A has been mounted to the frame 60. The protrusion 63B can engage with the second hole 53B formed in the second hinge component 52B of the second terminal cover 50B.

Consequently, when the first terminal cover 50A is attached, the protrusion 63B does not interfere with the first terminal cover 50A, and when the second terminal cover 50B is attached, the protrusion 63A does not interfere with the second terminal cover 50B, so the first terminal cover 50A and the second terminal cover 50B can be selectively attached to the cover attachment structure 1. Accordingly, a cover attachment structure 1 of the same configuration can be used for either the first terminal cover 50A or the second terminal cover 50B, which means that fewer parts are required across a plurality of models.

Also, in this embodiment, the cover attachment structure 1 comprises the restrictor 64A (an example of a first restrictor) and the restrictor 64B and the restrictor 642B (examples of a second restrictor). The restrictor 64A is provided on the frame 60 so as not to interfere with the second terminal cover 50B in a state in which the second terminal cover 50B has been mounted to the frame 60. The restrictor 64B and the restrictor 642B are provided on the frame 60 so as not to interfere with the first terminal cover 50A in a state in which the first terminal cover 50A has been mounted to the frame 60.

Consequently, when the first terminal cover 50A is attached, the restrictor 64B and the restrictor 642B do not interfere with the first terminal cover 50A, and when the second terminal cover 50B is attached, the restrictor 64A does not interfere with the second terminal cover 50B, so the first terminal cover 50A and the second terminal cover 50B can be selectively attached to the cover attachment structure 1, and the attached cover can be temporarily fixed by the restrictor or restrictors. Accordingly, when the cover is subsequently fixed by the side panel (an example of a housing member), movement of the cover away from the frame can be reduced, so the cover can be easily fixed.

As discussed above, with the digital camera 100A and the digital camera 100B, the side panel, terminal cover, and terminals are different in FIGS. 6 and 7, but the frame 60 is made up of the same parts. The restrictor 64A, the protrusion 63A, the protrusion 63B, the restrictor 64B, and the restrictor 642B are aligned on the frame 60 in that order from bottom to top. Also, the terminal 71 and the protrusion 63A are aligned in the forward and backward direction. The protrusion 63B is disposed in front of the approximate center of the terminal 71 and the terminal 72, which are aligned in the up and down direction.

This layout affords a frame 60 with which terminal covers of different widths can both be attached. Therefore, the same frame 60 can be used for the digital camera 100A and the digital camera 100B equipped with terminal covers of mutually different widths, and the number of parts required for these two models overall can be reduced.

### Other Embodiments

Embodiment 1 was described above as an example of the technology disclosed in this application. However, the text and drawings that form part of this disclosure should not be construed as limiting the technology in this disclosure. Various alternate embodiments, working examples, and application techniques should be clear to a person skilled in the art from this disclosure. Specifically, the technology in the disclosure can also be applied to embodiments that have undergone suitable modifications, substitutions, additions, omissions, and so forth. Also, the various constituent elements described in Embodiment 1 above may be combined into new embodiments.

The following are examples of other embodiments.

(A)

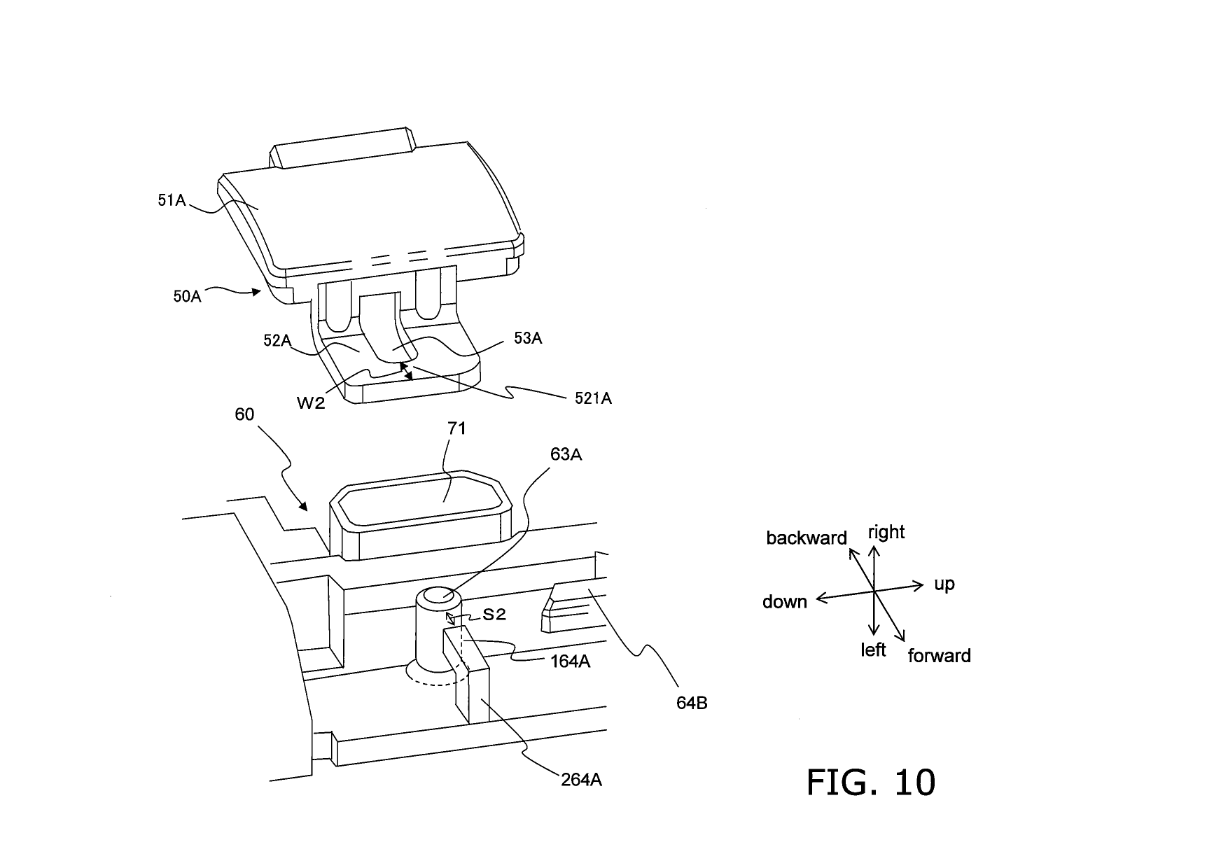

In the above embodiment, the restrictor 64A is provided under the protrusion 63A, but may be provided somewhere else. For example, it may be provided in front of the protrusion 63A, and may be configured to stick out toward the rear. FIG. 10 is an detail enlargement of the area near the protrusion 63A, and shows an example of such a configuration. The restrictor 164A shown in FIG. 10 is disposed on the front side of the protrusion 63A. The restrictor 164A is formed from the distal end of a protrusion 264A that sticks out to the right from the front step part 60A of the frame 60 like the protrusion 63A, in the direction of the protrusion 63A (rearward). In this case, the spacing S2 from the rear distal end of the restrictor 64A to the protrusion 63A is less than the width W2 of a portion 521A of the first hinge component 52A on the front side of the first hole 53A to prevent the first terminal cover 50A from moving away from the frame 60 from a state in which the protrusion 63A has been inserted into the first hole 53A. The restrictor 64B and the restrictor 642B may also have the same configuration.

(B)

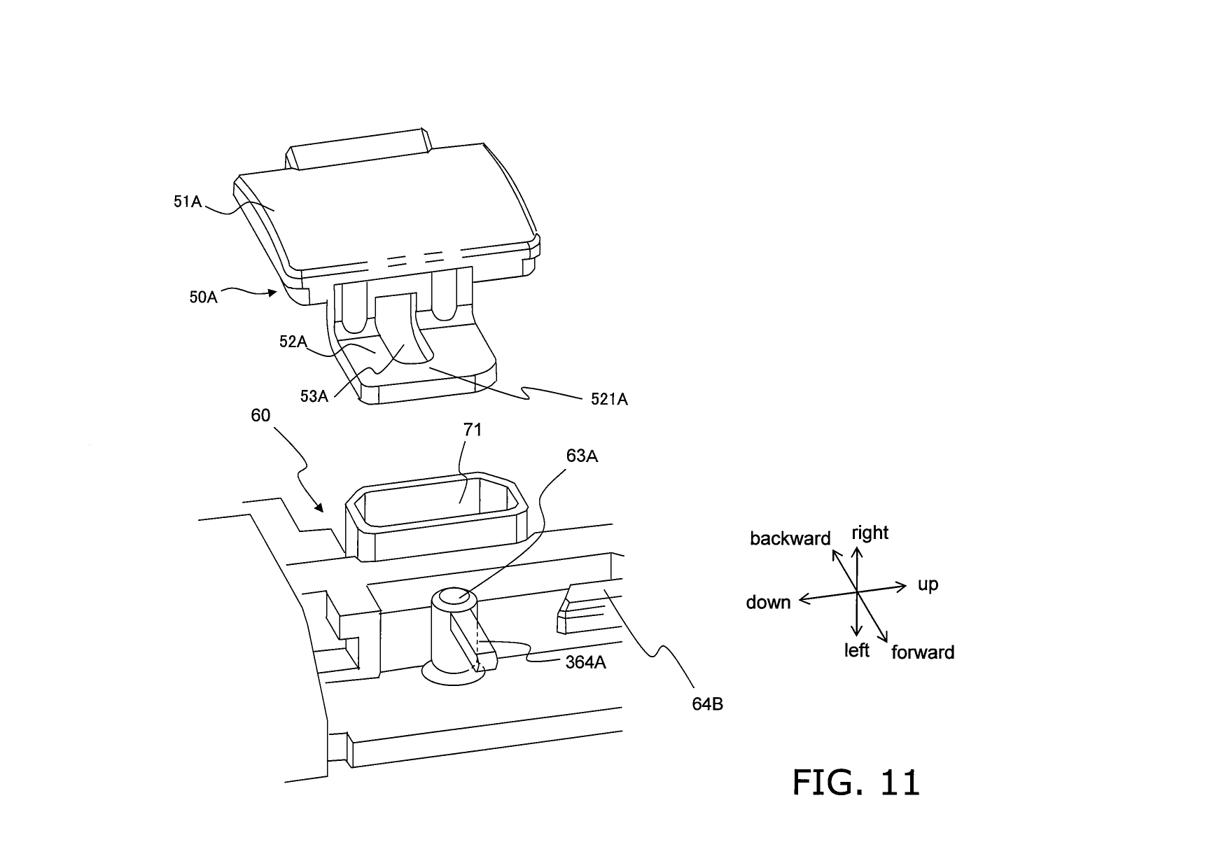

Also, the restrictor 64A may be provided so as to stick out either up, down, forward, or backward from the distal end of the protrusion 63A. FIG. 11 is a detail enlargement of the area near the protrusion 63A, and shows an example of such a configuration. The restrictor 364A shown in FIG. 11 is formed forward from the distal end of the protrusion 63A.

(C) The restrictor 64A may also be used in common with the restrictor 64B.

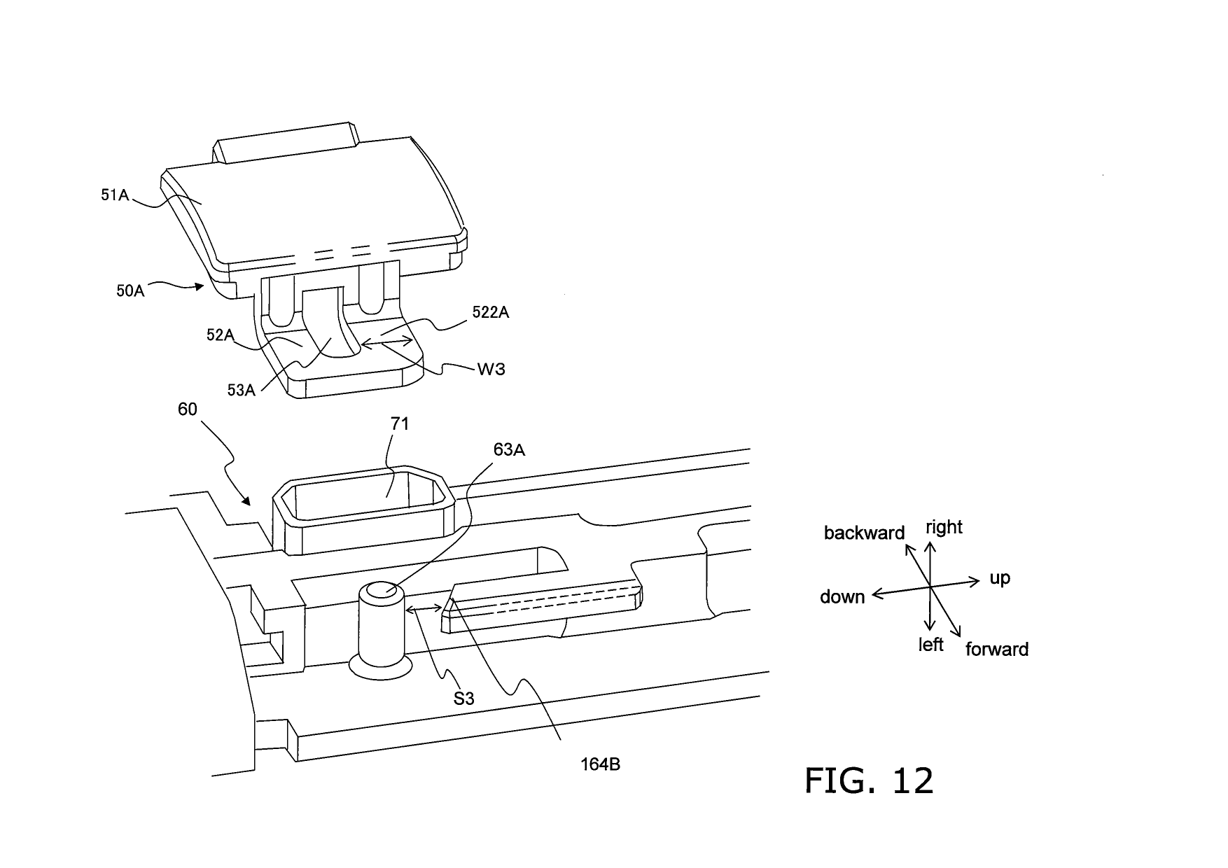

(C-1) Specifically, the restrictor 64B may be extended downward, the gap between the protrusion 63A and the distal end of the restrictor 64B made narrower than the part of the first hinge component 52A that is above the first hole 53A, and this used instead of the restrictor 64A. FIG. 12 is a detail enlargement of the area near the protrusion 63A, and shows such a configuration. The restrictor 164B shown in FIG. 12 is the result of extending the restrictor 64B shown in FIG. 7 downward. As discussed above, the spacing S3 between the protrusion 63A and the distal end of the restrictor 164B is made narrower than the width W3 of the portion 522A of the first hinge component 52A that is above the first hole 53A. This restrictor 164B corresponds to an example of a first restrictor that also serves as at least part of a second restrictor.

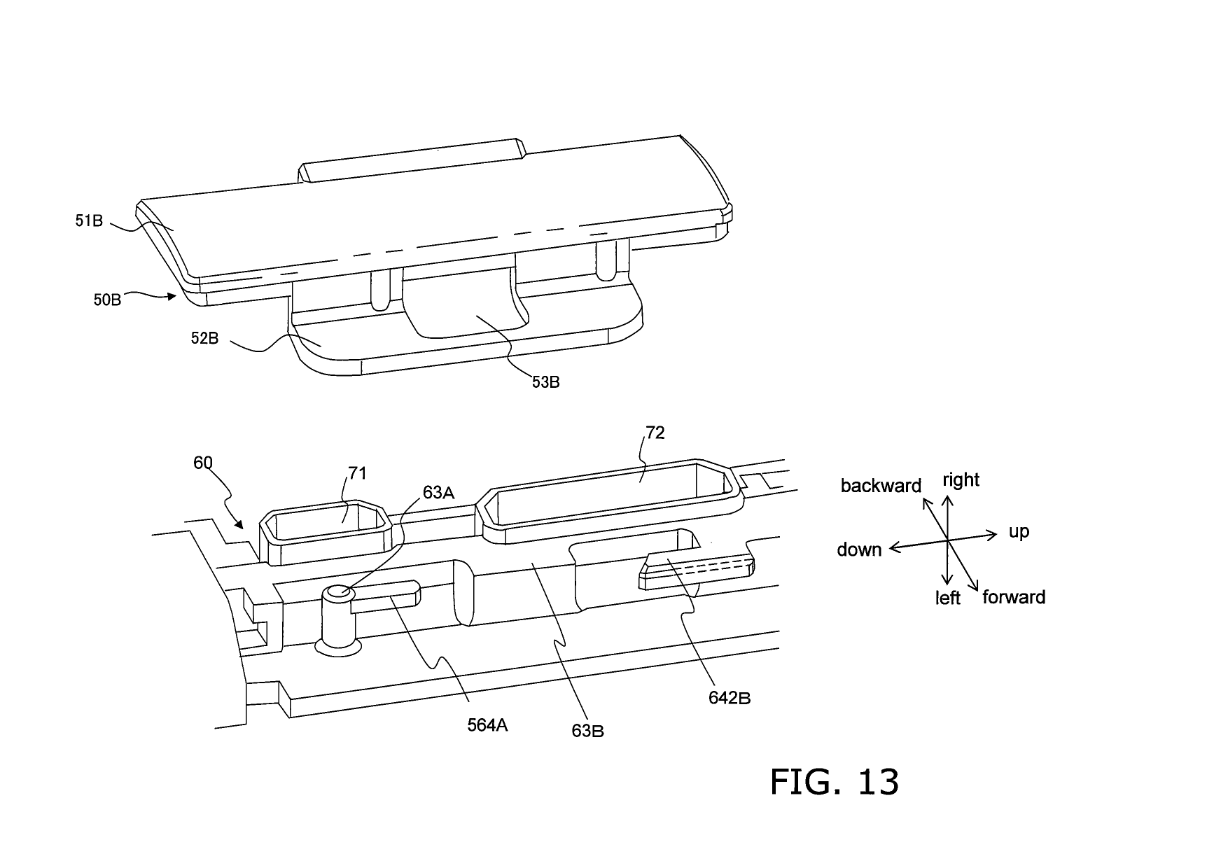

(C-2) As shown in FIG. 13, a restrictor 564A may be provided sticking out upward from the distal end of the protrusion 63A, and this restrictor 564A may function in place of the restrictor 64B. Specifically, the restrictor 564A corresponds to an example of a first restrictor that serves as at least part of a second restrictor, and when the second terminal cover 50B has been attached to the frame 60, it is restricted from moving away from the frame 60 by the restrictor 564A and the restrictor 642B.

(D)

In the above embodiment, the restrictor 64B and the restrictor 642B were provided as examples of a second restrictor to hold the second terminal cover 50B in place more reliably, but either the restrictor 64B or the restrictor 642B may be omitted.

(E)

The first attachment component and second attachment component are not limited to being the protrusion 63A and protrusion 63B.

(E-1)

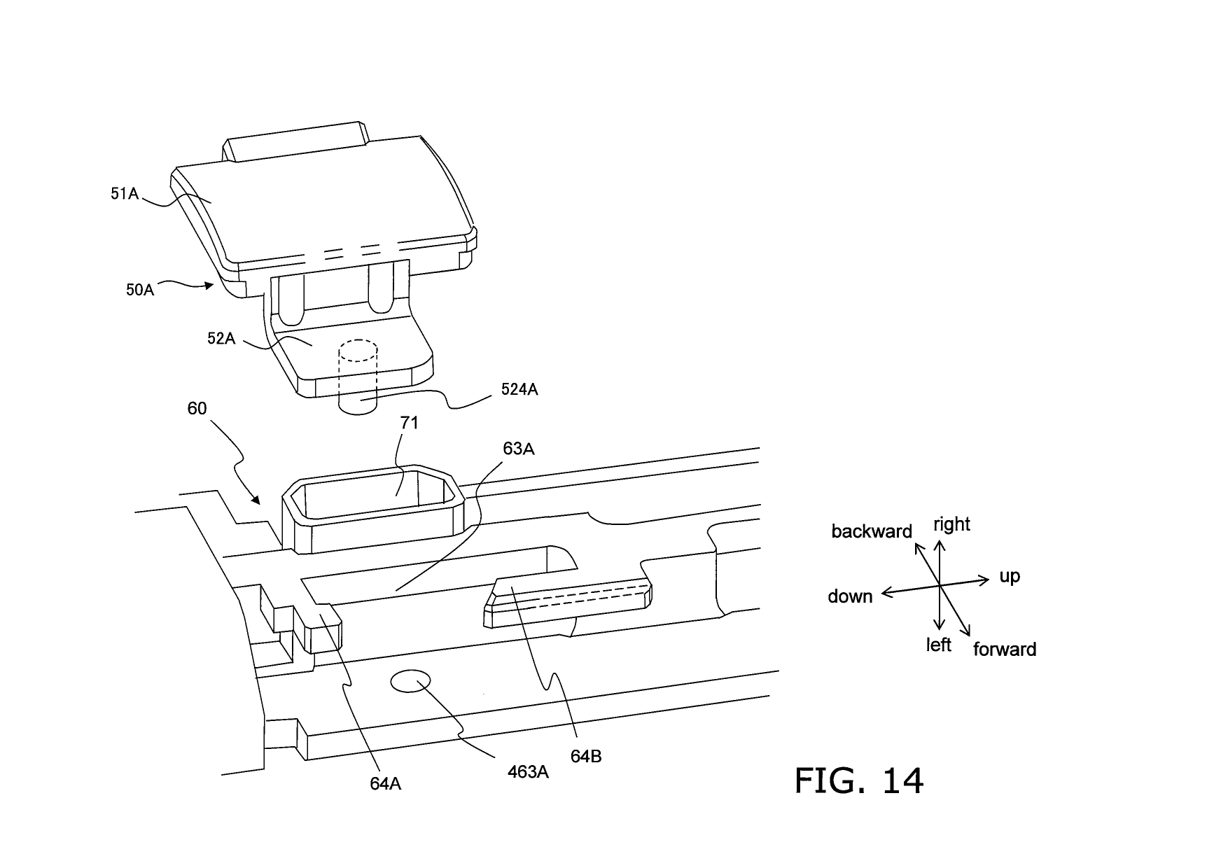

In the above embodiment, the protrusion 63A was described as an example of a first attachment component. The first attachment component need only allow the first terminal cover 50A (an example of a first cover) to be attached to the frame 60. Therefore, the first attachment component is not limited to being the protrusion 63A. For example, as shown in FIG. 14, the first attachment component may be a hole 463A formed in the frame 60. In this case, the first terminal cover 50A does not have the first hole 53A, and has a protrusion 524A formed sticking out to the left from the first hinge component 52A. The first terminal cover 50A is attached to the frame 60 by inserting this protrusion 524A into the hole 463A. In a state in which the first terminal cover 50A has been attached to the frame 60, the first terminal cover 50A is restricted from rotating and from moving away from the frame 60 by the restrictor 64A. Also, the position of the hole 463A may be a position covered by the second hinge component 52B in a state in which the second terminal cover 50B has been attached to the frame 60. Specifically, the position of the hole 463A (an example of a first attachment component) may be such a position on the frame 60 as interferes with the second hinge component 52B of the second terminal cover 50B in a state in which the second terminal cover 50B has been attached to the frame 60.This is because the hole 463A, unlike the protrusion 63A, does not interfere with the second terminal cover 50B in a state in which the second terminal cover 50B has been attached to the frame 60.

In other words, the first attachment component need only be provided on the frame 60 so as not to interfere with the second terminal cover 50B in a state in which the second terminal cover 50B has been attached to the frame 60.

(E-2)

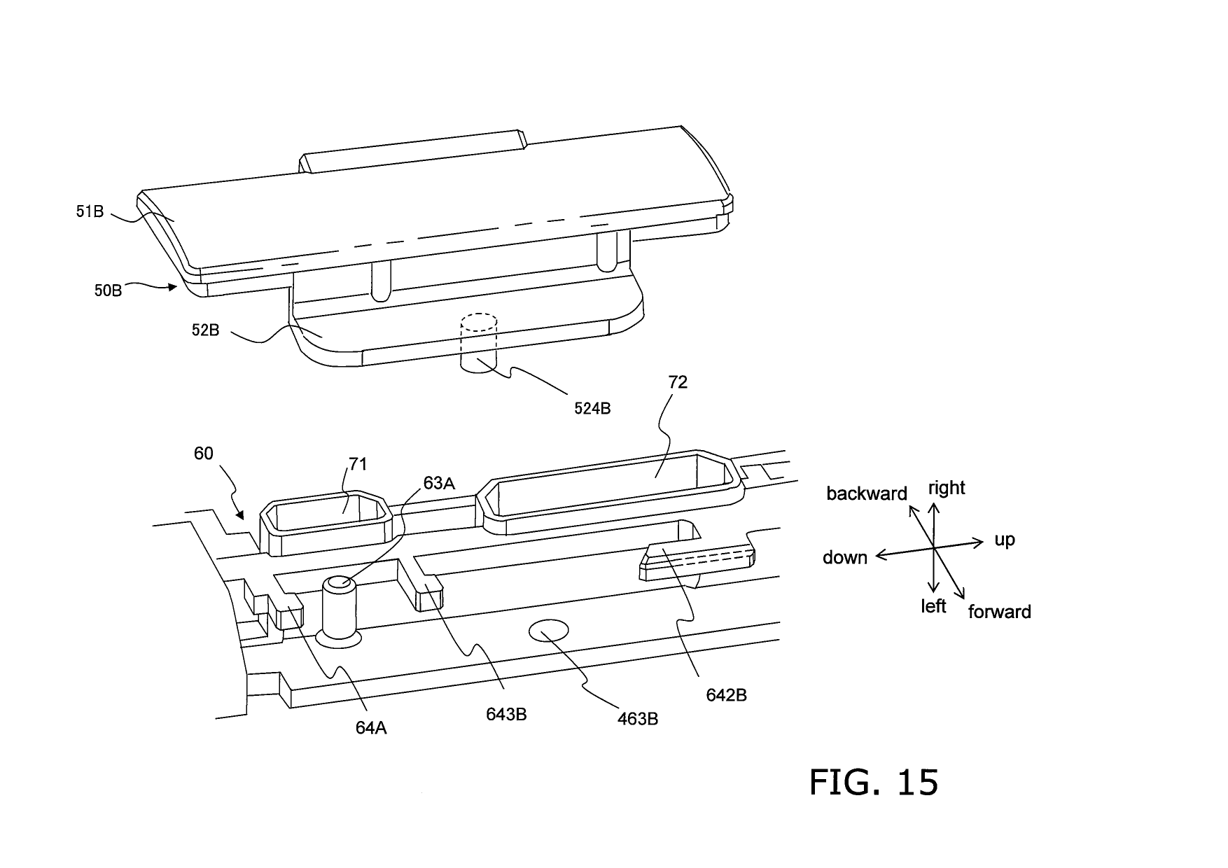

Also, in the above embodiment, the protrusion 63B was described as an example of a second attachment component. The second attachment component need only allow the second terminal cover 50B (an example of a second cover) to be attached to the frame 60. Therefore, the second attachment component is not limited to being the protrusion 63B. For example, as shown in FIG. 15, the second attachment component may be a hole 463B formed in the frame 60. In this case, the second terminal cover 50B does not have the second hole 53B, and has a protrusion 524B formed sticking out to the left from the second hinge component 52B. The second terminal cover 50B is attached to the frame 60 by inserting this protrusion 524B into the hole 463B. In FIG. 15, since the protrusion 63B is not provided, the restrictor 64B formed from the front end of the protrusion 63B is not provided, either, and a restrictor 643B is formed instead of the restrictor 64B. The restrictor 643B is disposed below the restrictor 642B, and is formed so as to stick out in the direction of the restrictor 642B. In a state in which the second terminal cover 50B has been attached to the frame 60, the second terminal cover 50B is restricted from rotating and from moving away from the frame 60 by the restrictor 643B and the restrictor 642B. Also, the position of the hole 463B may be a position covered by the first hinge component 52A in a state in which the first terminal cover 50A has been attached to the frame 60. Specifically, the position of the hole 463B (an example of a second attachment component) may be such a position on the frame 60 as interferes with the first hinge component 52A of the first terminal cover 50A in a state in which the first terminal cover 50A has been attached to the frame 60. This is because the hole 463B, unlike the protrusion 63B, does not interfere with the first terminal cover 50A in a state in which the first terminal cover 50A has been attached to the frame 60.

In other words, the second attachment component need only be provided on the frame 60 so as not to interfere with the first terminal cover 50A in a state in which the first terminal cover 50A has been attached to the frame 60.

(F)

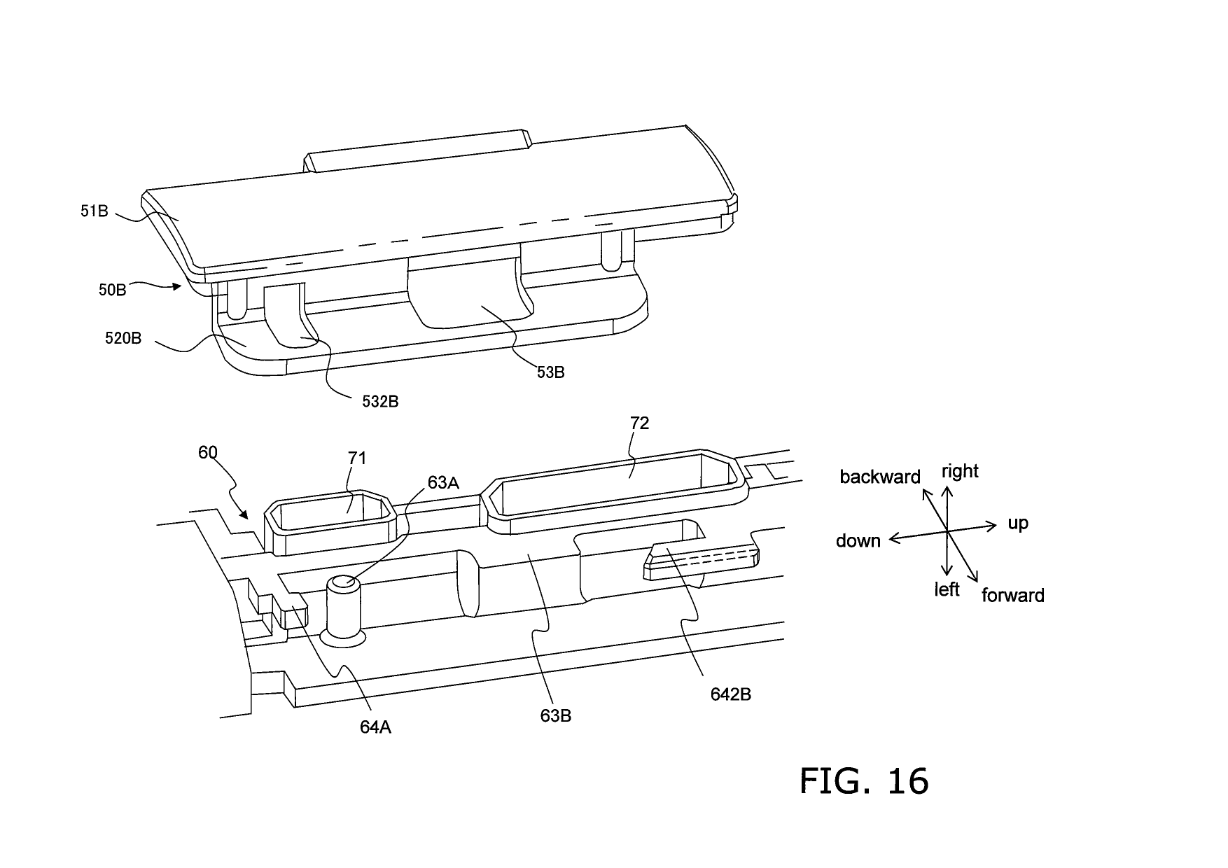

Also, in the above embodiment, the protrusion 63A is not utilized in the mounting of the second terminal cover 50B to the frame 60, but it may be used. FIG. 16 is an oblique view of a cover attachment structure, and shows an example of utilizing the protrusion 63A in the attachment of the second terminal cover 50B. A third hole 532B corresponding to the protrusion 63A is formed in addition to the second hole 53B in the second hinge component 52B of the second terminal cover 50B shown in FIG. 16. Therefore, the second hinge component 520B of the second terminal cover 50B in FIG. 16 is formed longer in the up and down direction than the second hinge component 52B in Embodiment 1. Also, the restrictor 64B is not provided to the frame 60 shown in FIG. 16. When the second terminal cover 50B is attached to the frame 60, the protrusion 63A is inserted into the third hole 532B, the protrusion 63B is inserted into the second hole 53B, and the second hinge component 520B goes under on the left side of the restrictor 642B and the restrictor 64A, which restricts the second hinge component 520B from moving away from the frame 60 and temporarily fixes the second terminal cover 50B to the frame 60. Specifically, the protrusion 63A and the protrusion 63B correspond to an example of a second attachment component, and the protrusion 63A (an example of a first attachment component) serves as part of the second attachment component.

(G)

In Embodiment 1, the protrusion 63B is formed so as to stick out forward from the riser part 60C, but may be provided away from the riser part 60C, as is the protrusion 63A. Also, the protrusion 63A may be formed so as to stick out from the riser part 60C as does the protrusion 63B.

(H)

In the above embodiment, a digital camera equipped with a cover that covers terminals was described as an example, but as long as it is used on an electronic device that shares parts across a plurality of models having covers of different sizes, the cover may be one that covers anything. For instance, it may be a cover that covers a memory card slot instead of a terminal.

Embodiments were described above as examples of the technology disclosed herein. To that end, the appended drawings and a detailed description were provided. Therefore, the constituent elements shown in the appended drawings and discussed in the detailed description may include not only the constituent elements that are essential to solving the problem, but also constituent elements that are not essential to solving the problem, in order to illustrate the above-mentioned technology. Therefore, just because these constituent elements that are not essential are shown in the appended drawings and discussed in the detailed description, it should not be concluded that these non-essential constituent elements are essential.

Also, the above embodiment was given to illustrate the technology disclosed herein, so various modifications, substitutions, additions, omissions, and so forth can be made within the scope of the patent claims and equivalents thereof.

### INDUSTRIAL APPLICABILITY

With the cover attachment structure disclosed herein, an electronic device can be provided with which parts can be shared across a plurality of models having covers of different sizes, and can therefore be utilized in the field of digital still cameras, digital video cameras, portable telephones, smart phones, personal computers, and other such electronic devices.

### REFERENCE SIGNS LIST

10 front panel

11 opening

20 rear panel

30 upper panel

40A side panel

40B side panel

41A hole

41B hole

42B hole

50A first terminal cover

50B second terminal cover

51A first cover part

51B second cover

52A first hinge component

52B second hinge component

53A first hole

53B second hole

60 frame

60A front step part

60B rear step part

63A protrusion

63B protrusion

64A restrictor

64B restrictor

642B restrictor

70 substrate

71 terminal

72 terminal

80 lens

100A digital camera

100B digital camera

1. A cover attachment structure used in an electronic device, said cover attachment structure comprising:
a frame configured so that one of a first cover for covering at least a first region and a second cover for covering a second region including the first region can be mounted selectively thereon so as to enable the mounted one of the first and the second cover to be opened and closed;
a first attachment component that is provided on the frame so as not to interfere with the second cover when the second cover has been mounted to the frame, and that can be engaged with the first cover; and
a second attachment component that is provided on the frame so as not to interfere with the first cover when the first cover has been mounted to the frame, and that can be engaged with the second cover.

2. The cover attachment structure according to claim 1, wherein:
the first cover includes a first hinge component;
the second cover includes a second hinge component;
the first attachment component has a first protrusion that is provided protruding from a position on the frame where there is no interference with the second hinge component when the second cover has been mounted to the frame, and that can engage with a first hole formed in the first hinge component, and
the second attachment component has a second protrusion that is provided protruding from a position on the frame where there is no interference with the first hinge component when the first cover has been mounted to the frame, and that can engage with a second hole formed in the second hinge component.

3. The cover attachment structure according to claim 1, comprising:
a first restrictor that is provided on the frame so as not to interfere with the second cover when the second cover has been mounted to the frame, and that restricts the first cover from moving away from the frame when the first cover is engaged with the first attachment component; and
a second restrictor that is provided on the frame so as not to interfere with the first cover when the first cover has been mounted to the frame, and that restricts the second cover from moving away from the frame when the second cover is engaged with the second attachment component.

4. The cover attachment structure according to claim 2, comprising:
a first restrictor that is provided on the frame so as not to interfere with the second hinge component when the second cover has been mounted to the frame, and that restricts the first hole from moving away from the first protrusion when the first protrusion is engaged with the first hole; and
a second restrictor that is provided on the frame so as not to interfere with the first hinge component when the first cover has been mounted to the frame, and that restricts the second hole from moving away from the second protrusion when the second protrusion is engaged with the second hole.

5. The cover attachment structure according to claim 3, wherein the first restrictor serves as at least part of the second restrictor.

6. An electronic device, comprising the cover attachment structure according to claim 1.

7. A cover attachment structure for an electronic device, said cover attachment structure comprising:
a frame including a first attachment portion configured to engage with a receiving portion of a first cover and a second attachment portion configured to engage with a receiving portion of a second cover, the first cover covering a first region of the frame, the second cover covering a second region of the frame including the first region,
wherein the frame includes first and second restricting portions for limiting movement of the one of the first cover and the second cover when covering the respective first region or second region,
wherein the first and second attachment portions and the first and second restricting portions are arranged so that the first cover can be mounted on the frame and opened and closed without substantial interference from the second attachment portion, and the second cover can be mounted on the frame and opened and closed without substantial interference from the first attachment portion.

8. The cover attachment structure according to claim 7, wherein
the receiving portions of the first cover and the second cover are first and second holes on first and second hinge components, respectively;
the first attachment component has a first protrusion that engages with the first hole of the first hinge component;
the second attachment component has a second protrusion that engages with the second hole of the second hinge component; and
the first protrusion and the second protrusion are arranged so that the first protrusion does not substantially interfere with the second hinge component when the second cover is closed and the second protrusion does not substantially interfere with the first hinge component when the first cover is closed.
